(19) United States
(12) Patent Application Publication
(10) Pub. No.: US 2008/0048216 A1
(43) Pub. Date: Feb. 28, 2008

(54) APPARATUS AND METHOD OF FORMING METAL OXIDE SEMICONDUCTOR FIELD-EFFECT TRANSISTOR WITH ATOMIC LAYER DEPOSITED GATE DIELECTRIC

(76) Inventors: Peide D. Ye, West Lafayette, IN (US); Yi Xuan, West Lafayette, IN (US); Han Chung Lin, West Lafayette, IN (US)

Correspondence Address: BARNES & THORNBURG LLP, 11 SOUTH MERIDIAN, INDIANAPOLIS, IN, 46204, US

(21) Appl. No.: 11/753,993

(22) Filed: May 25, 2007

Related U.S. Application Data
(60) Provisional application No. 60/809,195, filed on May 30, 2006.

(51) Int. Cl. H01L 21/335; H01L 29/78

(52) U.S. Cl. 257/288; 438/291; 257/E21.4; 257/E29.255

(57) ABSTRACT

A method for forming a metal oxide semiconductor field-effect transistor (MOSFET) includes forming a III-V compound semiconductor on a substrate with the III-V compound semiconductor being doped with a first dopant type. The method further includes doping a first and second region of the III-V compound semiconductor with a second dopant type to form a drain and a source of the MOSFET. The method further includes forming a gate dielectric on the III-V compound semiconductor through atomic layer deposition. The method further includes applying a metal onto the dielectric to form a gate of the MOSFET. A MOSFET is also disclosed herein.

### PRIORITY CLAIM

This Application claims priority to U.S. Provisional Patent Application Ser. No. 60/809,195 filed on May 30, 2006, the entirety of which is incorporated by reference herein.

### FIELD OF THE DISCLOSURE

The present invention relates generally to metal-oxide semiconductor field-effect transistors (MOSFETs), and more specifically to enhancement mode MOSFETs.

### BACKGROUND

Innovative device structures and gate dielectrics allow the advancement of developing Si complementary metal-oxide-semiconductor (CMOS) integration, functional density, speed and power dissipation, and extend CMOS front-end fabrication to and beyond the 22-nm node. One emerging strategy is to use III-V compound semiconductors as conduction channels, to replace traditional Si or strained Si, while integrating these high mobility materials with novel dielectrics and heterogeneously integrating them on Si or silicon-on-insulator (SOI). For more than four decades, the research community has been searching for suitable gate dielectrics or passivation layers on III-V compound semiconductors. One obstacle is the lack of high-quality, thermodynamically stable insulators on materials such as GaAs that can match the device criteria as SiO₂ on Si, e.g., a mid-bandgap interface-trap density (Dᵢₜ) of ˜10¹⁰/cm²-eV. Recently, in situ molecular beam epitaxy (MBE) growth of Ga₂O₃(Gd₂O₃) and ex situ atomic layer deposition (ALD) growth of Al₂O₃ attract particular attention. Research involving ALD high-k dielectrics is of particular interest, since the Si industry is getting familiar with ALD Hf-based dielectrics and this approach has the potential to become a manufacturable technology.

### SUMMARY

According to one aspect of the disclosure, a method of forming a metal oxide semiconductor field-effect transistor (MOSFET) includes forming a III-V compound semiconductor on a substrate with the III-V compound semiconductor being doped with a first dopant type. The method further includes doping a first and second region of the III-V compound semiconductor with a second dopant type to form a drain and a source of the MOSFET. The method further includes forming a gate dielectric on the III-V compound semiconductor through atomic layer deposition. The method further includes applying a metal onto the dielectric to form a gate of the MOSFET.

According to another aspect of the disclosure, a MOSFET includes a substrate and a III-V compound semiconductor formed on the substrate and being doped with a first dopant type. The III-V compound semiconductor includes a first region doped with a second dopant type to form a drain of the MOSFET and a second region doped with the second dopant type to form a source of the MOSFET. The MOSFET further includes a gate dielectric formed on the III-V compound semiconductor through atomic layer deposition. The MOSFET further includes a gate formed of metal disposed on the gate dielectric.

According to another aspect of the disclosure, a MOSFET includes a substrate and a III-V compound semiconductor formed on the substrate. The III-V compound semiconductor is doped with a first dopant type. The III-V semiconductor includes a drain region and source region each doped with a second dopant type. The MOSFET further includes a gate dielectric formed on the III-V compound semiconductor through atomic layer deposition. The MOSFET further includes a gate formed of metal on the gate dielectric.

### BRIEF DESCRIPTION OF THE DRAWINGS

The detailed description particularly refers to the accompanying figures in which:

FIG. 1(a) is a cross-sectional view of an illustrative metal-oxide semiconductor field-effect transistor (MOSFET) and an illustrative capacitor formed on the same wafer;

FIG. 1(b) is a plot of leakage current density versus gate bias of an illustrative MOSFET;

FIG. 2(a) is a plot of capacitance versus voltage of an illustrative MOS capacitor;

FIG. 2(b) is a plot of hysteresis versus frequency of an illustrative MOS capacitor;

FIG. 2(c) is a plot of accumulation capacitance versus frequency of an illustrative MOS capacitor;

FIG. 2(d) is a plot of flat band voltage versus frequency of an illustrative MOS capacitor;

FIG. 3(a) is a plot of capacitance versus voltage of an illustrative MOSFET;

FIG. 3(b) is a plot of current versus voltage of an illustrative MOSFET;

FIG. 4(a) is a cross-sectional view of another illustrative MOSFET;

FIG. 4(b) is a plot of drain-source current versus applied bias for an illustrative MOSFET;

FIG. 5(a) is a plot of channel resistance versus mask designed gate length of an illustrative MOSFET;

FIG. 5(b) is a plot of drain-source current versus gate voltage for an illustrative MOSFET;

FIG. 5(c) is a plot of drain-source current versus the inverse of mask designed gate length of an illustrative MOSFET;

FIG. 6(a) is a plot of capacitance versus voltage of an illustrative MOS capacitor; and

FIG. 6(b) is a plot of carrier mobility versus electric field for an illustrative MOSFET.

### DETAILED DESCRIPTION OF THE DRAWINGS

### First Illustrative Embodiment

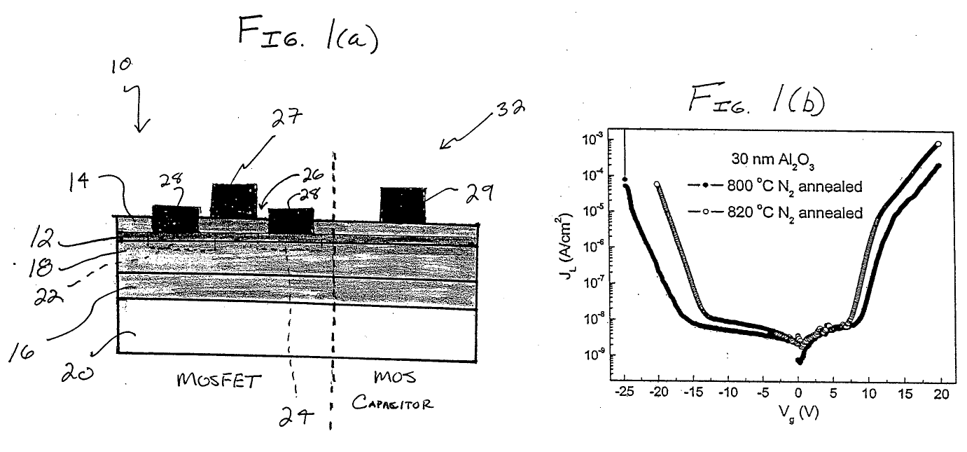

Referring now to FIG. 1(a), there is a cross-section of one illustrative embodiment of a device structure of a fabricated enhancement mode (E-mode) n-channel metal-oxide semiconductor field-effect transistor (MOSFET) 10 implementing a III-V compound semiconductor as a channel layer. In particular, FIG. 1 shows an illustrative embodiment of the MOSFET 10 implementing In_{0.2}Ga_{0.8}As as the channel layer 12 with Al₂O₃ serving as a high-k gate dielectric layer 14. A high-k dielectric such as Al₂O₃, can provide low defect density, low gate leakage, and high thermal stability. In this illustrative embodiment, the gate dielectric 14 is integrated on the channel layer 12 through atomic layer deposition (ALD).

In the illustrative device structure shown in FIG. 1(a), the MOSFET 10 further includes a buffer layer 16 and an intermediate layer 18. In the illustrative embodiment shown in FIG. 1, the channel layer 12, the buffer layer 16, and the intermediate layer 18 were sequentially grown by metal-organic chemical vapor deposition (MOCVD) on a substrate 20, shown in this illustrative embodiment as 2-inch GaAs p+. In one illustrative embodiment, the buffer layer 16 is a 150 nm p-doped 4×10¹⁷/cm³ In_{0.2}Ga_{0.8}As layer, the intermediate layer 18 is a 285 nm p-doped 1×10¹⁷/cm³ In_{0.2}Ga_{0.8}As layer, and the channel layer 12 is a 13.5 nm p-doped 1×10¹⁷/cm³ In_{0.2}Ga_{0.8}As channel layer. It should be appreciated that the methods described herein enable one of ordinary skill in the art to form various III-V compound semiconductors on compatible substrates that allow MOSFETs, such as the MOSFET 10, to be formed. Returning to the MOSFET 10, it should be appreciated that the doping concentrations of the layers 12, 16, and 18 can vary in range, such as in the order of 10¹⁶ to 10¹⁸, for example. In one illustrative embodiment, after appropriate surface pretreatment, 16 nm-30 nm ALD Al₂O₃ can be deposited at approximately 300° C. through atomic layer deposition. In one illustrative embodiment the ALD was performed using an ASM Pulsar2000™ ALD module, however it should be appreciated other devices can be used to perform the atomic layer deposition.

Compared to the conventional methods to form thin Al₂O₃ films, i.e., by sputtering, electron beam evaporation, chemical vapor deposition or oxidation of pure Al films, the ALD Al₂O₃ is typically of a much higher quality. ALD is an ultra-thin-film deposition technique based on sequences of self-limiting surface reactions enabling thickness control on atomic scale. The ALD high-k materials including Al₂O₃ can be used to substitute SiO₂ for sub-100 nm Si complementary MOSFET applications, as is conventionally used. ALD also allows the integration of high-quality gate dielectrics on non-Si semiconductor materials such as Ge, a high mobility channel material for p-type MOSFETs.

In the illustrative device structure of FIG. 1(a), the ALD Al₂O₃ gate dielectric 14 serves not only as a gate dielectric but also as an encapsulation layer due to its high thermal and chemical stability. In this illustrative embodiment, the source and drain regions 22, 24 are Si implanted that may be activated at 750-850° C. by rapid thermal annealing (RTA) in N₂ ambient. Dopant activation annealing is a step that not only activates the dopant, but may also preserve the smoothness of the interface at the atomic level. Using a wet etching in diluted hydrofluoric acid (HF) in the illustrative MOSFET 10, the oxide on the source and drain regions 22, 24 was removed, while the gate area 26 was protected by photoresist. It should be appreciated that the doping of a III-V compound semiconductor such as that disclosed regarding the MOSFET 10 can be varied. For example, the illustrative MOSFET 10 includes a p-type dopant in the channel layer 12 and an n-type dopant in the source 22 and drain regions 22, 24. However, in other embodiments, the channel layer 12 may include an n-type dopant and the source and drain regions 22, 24 may include a p-type dopant. This allows MOSFETs, such as the MOSFET 10, to be implemented for PMOS and NMOS configurations.

In one illustrative embodiment, ohmic contacts 28 were formed by electron-beam deposition of Au/Ge/Au/Ni/Au and a lift-off process, followed by an approximate 400° C. anneal in N₂ ambient. Conventional Ti/Au metals were e-beam evaporated, followed by lift-off to form the gate electrode 27. This illustrative process includes 4 levels of lithography (alignment, source and drain implantation, ohmic, and gate), which may all be done using a contact printer. The sheet resistance of the implanted source/drain regions 22, 24 and their contact resistances may be measured from transfer length method (TLM) to be ˜300 Ω/sq. and ˜1.0 Ω·mm, which, in this illustrative embodiment, demonstrates good process on implantation and activation. The designed gate lengths in various illustrative embodiments of the MOSFET 10 are 0.65, 0.85, 1, 2, 4, 8, 20 and 40 μm. It is not a self-aligned process. The overlap length between gate area 26 and source/drain 22, 24 is estimated around ˜0.5 μm or less.

Also shown in FIG. 1(a) is a capacitor 32, which is formed on the same wafer as the MOSFET 10. It should be appreciated that the capacitor 32 can be used for purposes of determining expected electrical characteristics of the MOSFET 10 and that in most practical applications the MOSFET 10 would be implemented separately.

Al₂O₃ dielectric films are highly electrically insulating. In this illustrative embodiment, the Al₂O₃ gate dielectric 14 shows very low leakage current density of ˜10⁹ to 10⁻⁸ A/cm² for amorphous films thicker than 6 nm. The leakage current density starts to increase after high temperature annealing, which is required to activate Si dopants implanted in GaAs. The increase of leakage currents is due to the creation of more leakage paths around crystallized grains in the amorphous films after high temperature annealing. As shown in FIG. 1(b), the leakage current density (J_{L}) is measured on 30 nm ALD Al₂O₃ versus the applied potential on the capacitor 32, gate bias V_{g}, with high annealing temperatures. The positive bias means that the metal electrode 29 is positive with respective to GaAs as shown in FIG. 1(a). The plot of FIG. 1(b) shows extremely low leakage current density in ALD Al₂O₃ films even after 800° C. (approximately) annealing, though a significant increase in current density exhibits with increasing annealing temperature up to approximately 820° C. An approximate temperature of 850° C. is the critical temperature when the crystallization in amorphous Al₂O₃ becomes severe and the leakage current increases dramatically.

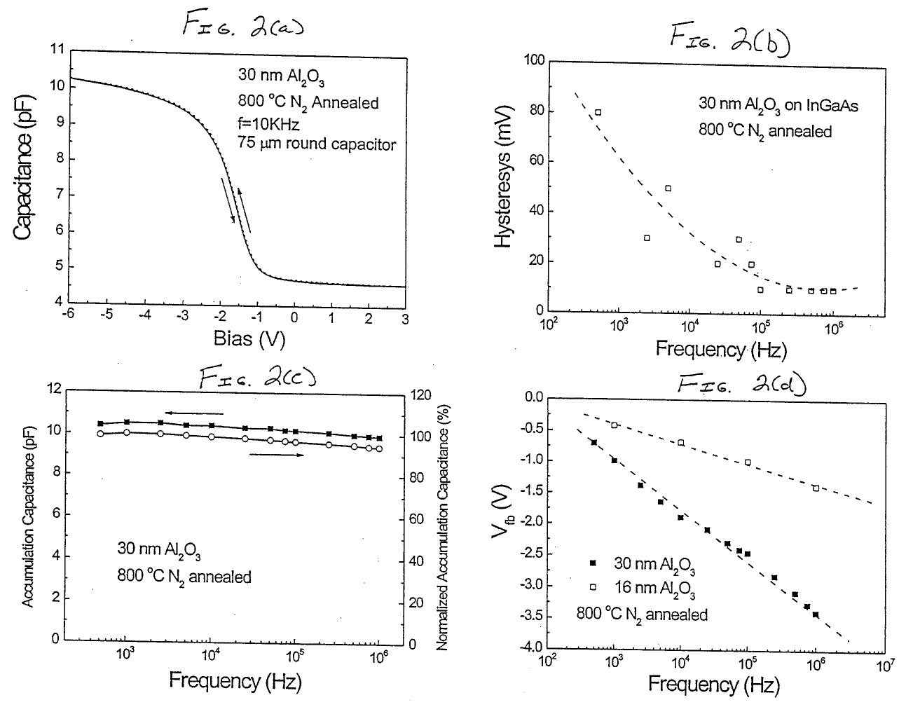

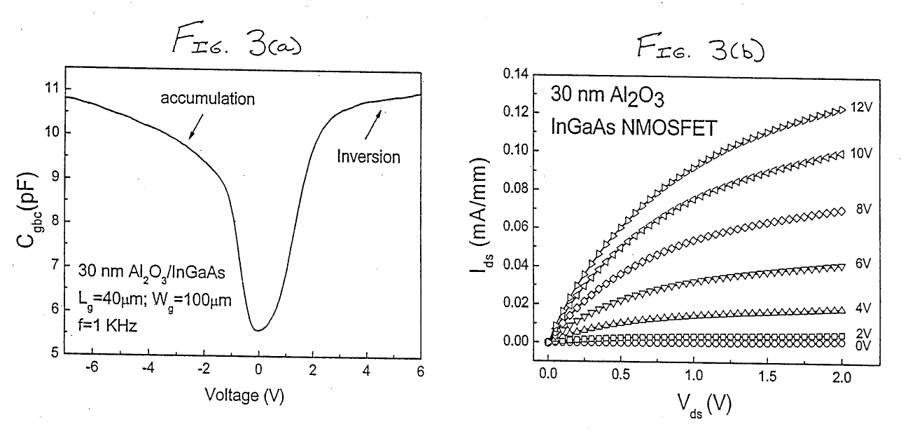

In one illustrative example, the high-quality of Al₂O₃/InGaAs interface surviving from high temperature annealing is verified by capacitance-voltage (C-V) curves showing sharp transition from depletion to accumulation with “zero” hysteresis, 1% frequency dispersion per decade at accumulation capacitance and strong inversion at split C-V measurement. (See FIGS. 2(a)-3(b).) For purposes of this disclosure, the term “split” refers to one terminal split into three, such as a source, drain, and back gate with all three ground together. Further, ALD Al₂O₃ allows an (E-mode) n-channel III-V MOSFET to have a true inversion channel formed at the high-k dielectric interface, such as the Al₂O₃/InGaAs interface of the MOSFET 10 shown in FIG. 1.

Illustrative C-V measurements on high temperature annealed ALD Al₂O₃ dielectrics on InGaAs and I-V (current-voltage) characterization on an illustrative fabricated E-mode InGaAs MOSFET 10 where the inversion channel is directly formed at the Al₂O₃/InGaAs interface are shown in FIGS. 3(a) and 3(b). Al₂O₃ may be used as an insulating material for a gate dielectric based upon its tunneling barrier and protection coating due to its excellent dielectric properties, strong adhesion to dissimilar materials, and thermal and chemical stability. Al₂O₃ typically has a high bandgap (˜9 eV), a high breakdown electric field ( approximately 5-30 MV/cm), a high permittivity (approximately 8.6-10) and high thermal stability (up to at least 1000° C.) and remains amorphous under typical processing conditions for implanted dopant activation on GaAs. It should be appreciated that other materials can be used as a dielectric in the MOSFET 10, such as HfO₂, ZrO₂, Ga₂O₃, Gd₂O₃, Y₂O₃, TiO₂, Ta₂O₅, La₂O₃, and their combinations such as HfAlO, TiAlO, and LaAlO. It should be further appreciated that a gate dielectric could be formed of SiO₂, Si₃N₄ formed by CVD (chemical vapor deposition) or PVD (physical vapor deposition) as an encapsulation layer.

C-V measurements allow a quantitative study of a MOS structure. From the C-V measurements, three quantities allowing the evaluation of high-k dielectrics on novel channel materials may be determined. The first is the amount of hysteresis that results when the MOS capacitor is biased well into accumulation and inversion. The second is the interface trap density Dᵢₜ at the interface showing in C-V curve how rapid the transition is between accumulation and inversion. The third is the frequency dispersion on accumulation capacitances and flat-band shifts. The C-V characterization of ALD Al₂O₃ on InGaAs may be observed after high temperature annealing, such as between 750° C.-850° C. for example, which is required to activate Si dopants in InGaAs. It should be appreciated that improved C-V curves or Dᵢₜ may be exhibited under annealing temperatures, such as those between 450° C.-600° C. for example, under a certain ambient or complicated annealing process. However, these curves are not directly relevant to the MOS interface needed for realizing inversion-channel E-mode GaAs MOSFET using implantation process.

The high-frequency (10 kHz) C-V curves for the illustrative capacitor 32 with a 30 nm ALD Al₂O₃ on InGaAs is shown in FIG. 2(a). This illustrative capacitor 32 experienced all the various device processes previously described herein and was annealed with an RTA step of approximately 800° C. for approximately 10 seconds in nitrogen ambient. In this illustrative embodiment, the solid curve in FIG. 2(a) is measured from −5 V to +3 V with the sweep rate ˜4V/min., while the dashed curve is taken from +3 V to −5 V. The solid and dashed curves indicate substantially “zero” hysteresis in this C-V loop with the maximum shift less than 20 mV.

FIG. 2(b) illustrates the hysteresis versus frequency observed on a typical MOS capacitor, such as the MOS capacitor 32. The hysteresis of FIG. 2(b) is in the range of 10-50 mV between 1 KHz-1 MHz, and increases as the frequency goes down in general. The extremely low hysteresis illustratively shown in FIG. 2(b), along with the sharp transition from depletion and accumulation, indicates the high quality of bulk and interface properties of ALD Al₂O₃ on InGaAs even after high temperature annealing. The effects of the annealing step on the chemical and structural properties of the interface are very complex and outside the scope of this disclosure.

It should be appreciated that the frequency dispersion on accumulation capacitance Cₘₐₓ is another issue for consideration regarding high-k dielectrics on III-V materials. In one illustrative embodiment of the MOSFET 10, this dispersion could be as large as 50% or more in the frequency range of 1 kHz to 1 MHz, which stymies all efforts to estimate Dᵢₜ using high-low frequency capacitance method. FIG. 2(c) illustratively summarizes the accumulation capacitance Cₘₐₓ measured on exemplary 800° C. annealed capacitors 32 in the wide frequency range from 500 Hz up to 1 MHz. The frequency dispersion is only 1% per decade at this frequency range. This experiment illustratively demonstrates that the major part of frequency dispersion on a non-ideal oxide/III-V material interface does relate to the interface properties instead of simple parasitic effect, which may be corrected by two-frequency correction or multi circuit element models. The dielectric constant is ˜8.1 deduced from the measured maximum accumulation capacitance Cₘₐₓ, the area of the capacitor 32, and the dielectric film thickness. The flat band shift is also an issue of interest at the beginning for alternative dielectrics research on Si. Of note is the observed frequency dependent flat band shift of 800° C. annealed capacitors. FIG. 2(d) illustratively shows the summary of the flat band voltage V_{fb} versus frequency on exemplary 16 nm and 30 nm thick ALD Al₂O₃ films. In this illustrative example, the frequency dependent flat band shift is much less on medium temperature (450° C.-600° C.) annealed capacitors 32. This phenomenon is less significant on 16 nm thick film compared to 30 nm thick one. It is roughly scaled with the film thickness and linearly dependent on log(frequency).

In one illustrative embodiment, clear n-channel inversion on p-type InGaAs is realized at Al₂O₃/InGaAs interface, which is demonstrated by measuring C_{gbc}, the capacitance measured from the gate 118 when the source 108, drain 110, and back gate (not shown) are all grounded, (via split-C-V method) on MOSFETs, such as the MOSFET 10, as illustratively shown in FIG. 3(a). The C-V curve is taken on an exemplary MOSFET 10 with a 40 μm gate length and a 100 μm gate width at frequency as high as 1 kHz. At the conventional MOS configuration as measured in FIG. 2(a), no n-channel inversion is observed at frequencies as low as 100 Hz. It should be appreciated that the minority carriers (electrons) are provided by the source and drain diffusions and not by thermal generation in the depletion region. In the split C-V or MOSFET configuration with source and drain grounded at the same time, majority (holes) and minority (electrons) carrier capacitances may be measured independently at the same frequency. In one illustrative embodiment, using a low-frequency capacitance of C_{LF}=5.5 pF, a high-frequency capacitance of C_{HF}=5.0 pF, and an oxide capacitance of Cₒₓ=11.0 pF, the middle gap interface trap density Dᵢₜ is determined to be 2.9×10¹¹/cm²-eV.

FIG. 3(b) shows the I-V characteristics of an illustrative 1×100 μm² gate geometry E-mode n-channel InGaAs MOSFET 10 with ALD Al₂O₃ as a gate dielectric, such as that shown in FIG. 1(a). In this illustrative example, the gate voltage is varied from 12 to 0 V in steps of −2 V and the threshold voltage, V_{T}, is ˜0. It is believed that the low drain current could be improved by optimizing implant and annealing conditions to reduce parasitic resistance and surface scattering. The maximum drain current on the illustrative MOSFET 10 device is ˜0.12 mA/mm, which is comparable to the GaAs based E-mode MOSFET 10 reported known at Ga₂O₃(Gd₂O₃)/GaAs interface. It should be appreciated that by combining the C-V result in FIG. 3(a) and the I-V result in FIG. 3(b), it is clearly demonstrated that the true inversion n-channel can be formed at ALD Al₂O₃/InGaAs interface.

### Second Illustrative Embodiment

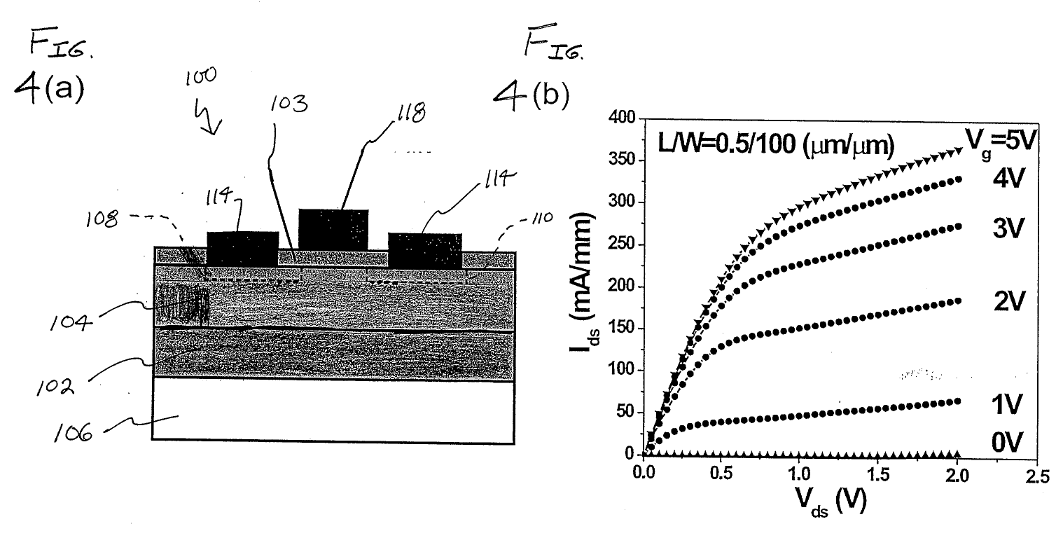

FIG. 4(a) shows the cross-sectional diagram of an ALD Al₂O₃/In_{0.53}Ga_{0.47}As MOSFET 100. It should be appreciated that, based upon the descriptions of both MOSFETs 10, 100 described herein, that III-V compound semiconductors, for purposes of this disclosure, can include varied amounts of a particular element with respect to the other elements in the compound. For example, In can elementally make up about 15%-100% of the III-V compound semiconductors used in forming MOSFETs 10, 100. Returning to the MOSFET 100, a 500 nm p-doped 4×10¹⁷ cm⁻³ buffer layer 102, and a 300 nm p-doped 1×10¹⁷ cm⁻³ In_{0.53}Ga_{0.47}As channel layer 104 that were sequentially grown by MBE on a 2-inch InP p+ substrate 106. In one illustrative embodiment, after surface degreasing and ammonia-based native oxide etching, wafers including the buffer layer 102, channel layer 104, and substrate 106 were transferred via room ambient to an ASM F-120 ALD reactor. In this embodiment, a 30 nm thick Al₂O₃ dielectric layer 103 was deposited at a substrate temperature of approximately 300° C. as an encapsulation layer. A source region 108 and a drain region 110 were selectively implanted with a Si dose of 1×10¹⁴ cm⁻² at 30 keV and 1×10¹⁴ cm⁻² at 80 keV through the 30 nm thick Al₂O₃ layer. Implantation activation was achieved by RTA at approximately 650-850° C. for 10 seconds in a nitrogen ambient. An 8-nm Al₂O₃ film was regrown by ALD after removing the encapsulation layer by BOE solution and ammonia sulfide surface preparation. After approximately 600° C. PDA process, source and drain ohmic contacts 114 were made by an electron beam evaporation of a combination of AuGe/Ni/Au and a lift-off process, followed by a RTA process at approximately 400° C. for 30 seconds also in a N₂ ambient. A gate electrode 118 was defined by electron beam evaporation of Ni/Au and a lift-off process. The fabricated MOSFETs 100 have a nominal gate length varying from approximately 0.50 μm to 40 μm and a gate width (not shown) of approximately 100 μm. In one illustrative embodiment, an HP4284 LCR meter was used for the capacitance measurement and a Keithley 4200 was used for output characteristics of the MOSFET 100.

FIG. 4(b) shows the dc I_{ds}(drain current)−V_{ds}(applied bias) characteristics of the MOSFET 100 for one illustrative embodiment with a gate bias from 0 to 5V in steps of +1 V. The characteristics shown in FIG. 4(b) are for an embodiment of a MOSFET 100 having a mask designed gate length L_{Mask} of approximately 0.50 μm and gate width of approximately 100 μm. In one illustrative embodiment, a maximum drain current of 367 mA/mm is obtained at a gate bias of 5 V and a drain bias of 2 V. In this illustrative embodiment, the MOSFET 100 performance has a significant leap with 3000 times increase of the maximum drain current, compared to the results discussed in regard to the first illustrative embodiment implementing In_{0.20}Ga_{0.80}As, such as the MOSFET 10. In one illustrative embodiment, the gate leakage current is below 1.4 μA/mm under the same bias condition used in regard to the MOSFET 10, more than five orders of magnitude smaller than the drain on-current. The source-drain leakage current is another issue for narrow bandgap semiconductor devices caused mainly by drain-induced-barrier-lowing (DIBL) effect and impact ionization. As shown in FIG. 4(b), the source-drain leakage current at zero gate bias is between approximately 1 μA to 100 μA at V_{ds}=2V.

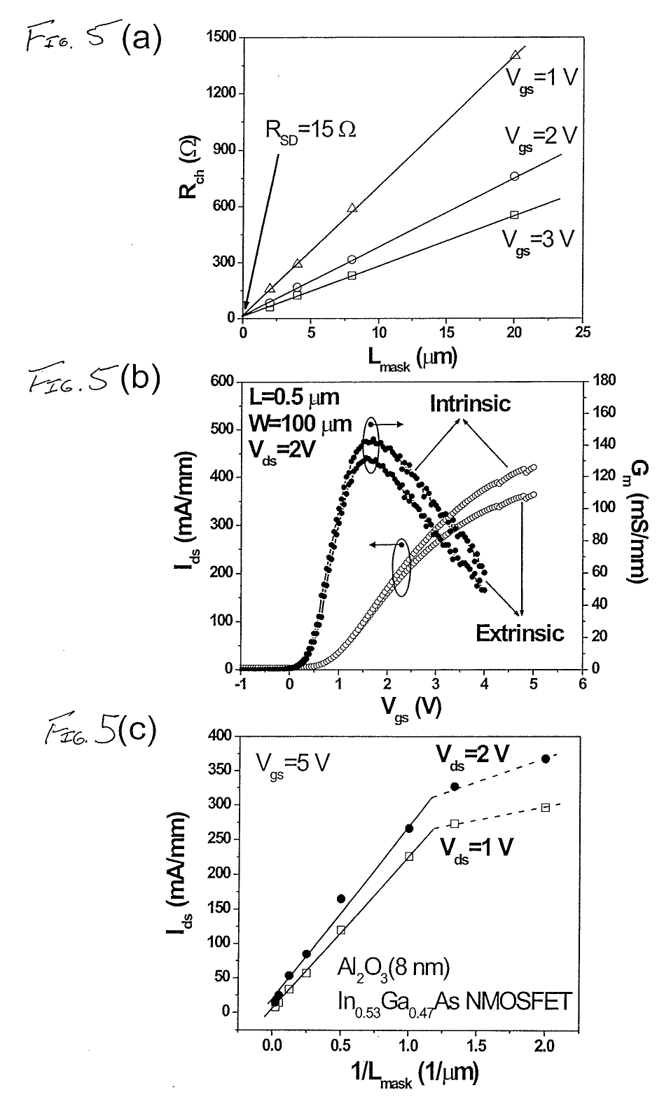

Since the fabrication process used is typically not a self-aligned process, accurate determination of the effective gate length and series resistance is important in evaluation of the intrinsic device performance and the potential for further optimization. FIG. 5(a) shows an illustrative effective gate length L_{eff} and a series resistance R_{SD} extracted by plotting measured channel resistance R_{Ch} vs. L_{Mask}. Here, R_{Ch} is the measured channel resistance and Lₘₐₛₖ is the mask designed gate length. The series resistance R_{SD} and the difference between Lₘₐₛₖ and L_{eff}, designated as ΔL, are determined to be 15Ω and <0.05 μm, respectively. ΔL is negligible in this work so that L_{Mask}=L_{eff}≈L.

In this embodiment, a maximum extrinsic transconductance Gₘ is approximately 130 mS/mm and on-resistance is only 2 Ω·mm at V_{g}=5V. The extrinsic transconductance Gₘ could be further improved by reducing the thickness of the dielectric and improving the quality of the interface. To evaluate the output characteristics more accurately, the intrinsic transfer characteristics are calculated by subtracting half of the series resistance R_{SD} and are compared with extrinsic ones in FIG. 5(b). The resulting intrinsic maximum drain current I_{ds} and transconductance Gₘ for 0.5 μm device are 425 mA/mm and 145 mS/mm, respectively. By the conventional linear region extrapolation method or second derivative method, the extrinsic threshold voltage is determined around 0.25 V in one illustrative embodiment. The threshold voltage can be finely tuned by channel doping and metal work function to fulfill the specific requirements for different applications. The subthreshold slope and DIBL for one particular embodiment of the MOSFET 100 are 260 mV/dec and 400 mV/V, respectively.

FIG. 5(c) summarizes all measured drain current I_{ds} vs. 1/Lₘₐₛₖ under V_{gs}=5V and V_{ds}=2V or V_{ds}=1V for the illustrative MOSFET 100. The drain current or transconductance Gₘ is linearly inversely proportional to the mask designed gate length Lₘₐₛₖ as expected and start to saturate at approximately Lₘₐₛₖ=0.75 μm. In other illustrative embodiments, the surface preparation and high-k dielectric formation process may be optimized, such that the drain current and transconductance Gₘ could increase at least a factor of 2-3 further.

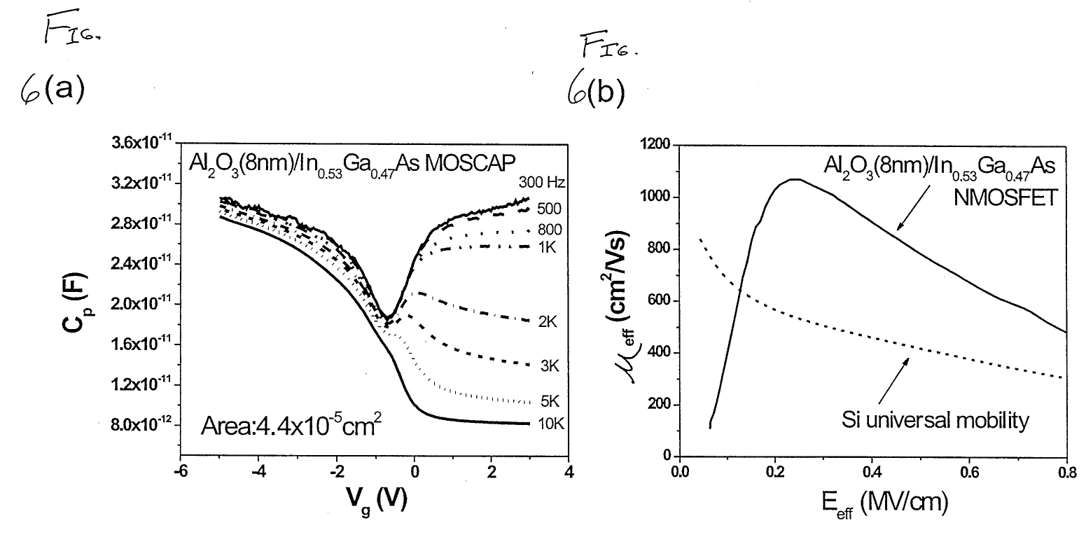

As similarly shown in regard to the MOSFET 10, detailed C-V measurements of MOS capacitors, fabricated on the same device wafers, may also carried out to evaluate the interface quality of ALD Al₂O₃ on In_{0.53}Ga_{0.47}As as illustratively shown in FIG. 6(a). The high-frequency (HF) C-Vat 10 kHz shows a clear transition from accumulation to depletion for a typical p-type MOS capacitor. The inversion features of low-frequency (LF) C-V from 1 kHz down to 300 Hz indicate that the conventional Fermi-level pinning phenomenon on III-V is overcome in this ALD-Al₂O₃/In_{0.53}Ga_{0.47}As interface. It is believed that the small (3% per decade) frequency dispersion at accumulation capacitance to the relative high Dᵢₜ at the conduction band edge, though the extrinsic parasitic effects could also contribute to it. The mid-gap Dᵢₜ is estimated to be around 1.4×10¹²/cm²-eV determined by HF-LF method. Moderate hysteresis of 100-300 mV exhibits in the C-V loops (not shown).

Effective mobility is another important parameter to evaluate the MOSFET 100 performance. A split C-V method is used to measure the channel capacitance of a 40-μm-gate-length device which can be used to calculate the total inversion charge in the channel by integrating the C-V curve. The extracted effective mobility μ_{eff} has a peak value of 1100 cm²/Vs around a normal electric field E_{eff} of 0.25 MV/cm and twice higher μ_{eff} than Si universal mobility at E_{eff} of 0.50 MV/cm as shown in FIG. 6(b). A better mobility performance is expected to be achievable by further optimizing dielectric formation and device fabrication process.

There are a plurality of advantages of the present disclosure arising from the various features of the apparatus and methods described herein. It will be noted that alternative embodiments of the apparatus and methods of the present disclosure may not include all of the features described yet still benefit from at least some of the advantages of such features. Those of ordinary skill in the art may readily devise their own implementations of an apparatus and method that incorporate one or more of the features of the present disclosure and fall within the spirit and scope of the present disclosure.

1. A method of forming a metal oxide semiconductor field-effect transistor (MOSFET), the method comprising:
forming a III-V compound semiconductor on a substrate, the III-V compound semiconductor being doped with a first dopant type,
doping a first and second region of the III-V compound semiconductor with a second dopant type to form a drain and a source of the MOSFET,
forming a gate dielectric on the III-V compound semiconductor through atomic layer deposition, and
applying a metal onto the dielectric to form a gate of the MOSFET.

2. The method of claim 1, wherein the forming a III-V compound semiconductor comprises forming InGaAs on GaAs, the InGaAs being doped with a first dopant type.

3. The method of claim 1, wherein the forming a III-V compound semiconductor comprises forming InGaAs on InP, the InGaAs being doped with a first dopant type.

4. The method of claim 1, wherein the forming a III-V compound semiconductor comprises forming In_{0.53}Ga_{0.47}As on InP, the InGaAs being doped with the first dopant type.

5. The method of claim 3, wherein the forming a III-V compound semiconductor comprises forming InGaAs on InP, the InGaAs being doped with a p-type dopant.

6. The method of claim 5, wherein the doping a first and second region comprises doping a first and second region of the semiconductor with an n-type dopant to form a drain and a source of the MOSFET.

7. The method of claim 1, wherein the forming a gate dielectric to a III-V compound semiconductor comprises forming a gate dielectric to a III-V compound semiconductor where the gate dielectric is selected from a group consisting of HfO₂, ZrO₂, Ga₂O₃, Gd₂O₃, Y₂O₃, TiO₂, Ta₂O₅, La₂O₃, HfAIO, TiAlO, and LaAlO.

8. The method of claim 4, wherein the forming a gate dielectric comprises forming Al₂O₃ on the InGaAs through atomic layer deposition.

9. The method of claim 8, wherein the applying a metal comprises placing a Ti/Au alloy onto the Al₂O₃ to form a gate of the MOSFET.

10. A metal oxide semiconductor field-effect transistor (MOSFET) comprising:
a substrate,
a III-V compound semiconductor formed on the substrate and being doped with a first dopant type, the III-V compound semiconductor comprising:
i) a first region doped with a second dopant type to form a drain of the MOSFET, and
ii) a second region doped with the second dopant type to form a source of the MOSFET,
a gate dielectric formed on the III-V compound semiconductor through atomic layer deposition, and
a gate formed of metal disposed on the gate dielectric.

11. The MOSFET of claim 10, wherein:
the substrate is GaAs, and
the III-V compound semiconductor is InGaAs.

12. The MOSFET of claim 11, wherein:
the substrate is InP, and
the III-V compound semiconductor is InGaAs.

13. The MOSFET of claim 12, wherein the InGaAs comprises about 15% to 100% In.

14. The MOSFET of claim 12, wherein the III-V compound semiconductor is In_{0.53}Ga_{0.47}As.

15. The MOSFET of claim 10, wherein the first dopant type is a p-type dopant.

16. The MOSFET of claim 15, wherein the second dopant type is an n-type dopant.

17. The MOSFET of claim 10, wherein the first dopant type is an n-type dopant.

18. The MOSFET of claim 17, wherein the second dopant type is a p-type dopant.

19. The MOSFET of claim 10 further comprising:
a first ohmic contact disposed on the first region of the III-V compound semiconductor, and
a second ohmic contact disposed on the second region of the III-V compound semiconductor.

20. A metal oxide semiconductor field-effect transistor (MOSFET) comprising:
a substrate,
a III-V compound semiconductor formed on the substrate and being doped with a first dopant type, the III-V semiconductor having a drain region and source region each doped with a second dopant type,
a gate dielectric formed on the III-V compound semiconductor through atomic layer deposition, and
a gate formed of metal on the gate dielectric.
